(19) United States
(12) Patent Application Publication
(10) Pub. No.: US 2007/0152306 A1
(43) Pub. Date: Jul. 5, 2007

(54) Semiconductor device and fabrication method thereof

(75) Inventors: Chien-Hsueh Shih, Taipei (TW); Shau-Lin Shue, Hsinchu (TW); Mong-Song Liang, Hsinchu (TW); Chao-Hsien Peng, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/324,334

(22) Filed: Jan. 4, 2006

(51) Int. Cl. H01L 23/58; H01L 21/4763

(52) U.S. Cl. 257/642; 438/725; 257/758; 438/622; 257/E23.145

(57) ABSTRACT

A semiconductor device and fabrication method thereof. The semiconductor device comprises a substrate, an electroactive organic layer with conformal step coverage and uniform thickness, and a metal layer. The substrate is a conductive substrate or a nonconductive substrate with a conductive layer formed thereon. The electroactive organic layer and the metal layer are formed sequentially on the conductive substrate or the conductive layer, wherein the electroactive organic layer comprises metal atoms and serves as a seed layer, resulting in the metal layer formed in-situ.

### BACKGROUND

The invention relates to a semiconductor device and fabrication method thereof and, more particularly, to a trench interconnection and fabrication method thereof.

Aluminum and aluminum alloys have been the most widely used interconnection metallurgies for integrated circuits. However, it has become more and more important that metal conductors forming interconnections between devices as well as between circuits in a semiconductor have low resistivity for faster signal propagation. Copper is preferred for its low resistivity as well as for resistance to electromigration (EM) and stress voiding properties for very and ultra large scale integrated. (VLSI and ULSI) circuits.

FIGS. 1a to 1c are a series of cross sections illustrating the process flow of a conventional copper trench interconnection. First, a silicon substrate 12 is provided. The substrate 12 is etched to form a trench 16 therein by lithography. Next, a seed layer of copper 20 is conformally formed by physical vapor deposition (PVD) on the substrate 12 covering the sidewalls and the bottom wall of the trench 16. Unfortunately, since copper is a mid-bandgap impurity in silicon and silicon dioxide, copper ions may diffuse easily into these common integrated circuit materials, such as dielectric layer with low dielectric constant.

In order to prevent copper ions from diffusing into the substrate 12 and degrading the performance of the integrated circuit, a diffusion barrier layer 18, such as W, is deposited on the substrate 12, covering the sidewalls and the bottom wall of the trench 16 before forming a seed layer of copper 20. Accordingly, the diffusion barrier layer 18 is disposed between the seed layer of copper 20 and the substrate 12 to preserve the integrity of the substrate 12.

With such an interconnect fabrication, referring to FIG. 2a, when the aspect ratio (defined as the depth (D) to the width (W), D/W)) of the trench 16 electroplated to fill with copper is relatively large (i.e., greater than 5:1), the seed layer 20 deposited by PVD on the sidewalls and the bottom wall of the trench 16 may result in significant overhangs 22 at the top corners of the trench 16, due to the PVD's-non-conformal step coverage.

Referring to FIGS. 2a and 2b, when copper filler 24 is plated sequentially from the seed layer 20, the copper plated from the overhang 22 may close off the top of the trench 16 before a center portion of the trench 16 is filled with copper, resulting in poor or incomplete filling of the trench 16. Such a void 26 disadvantageously increases the resistance of interconnect and may even contribute to electromigration-based failure of interconnect.

Referring to FIG. 3a, to minimize the overhang 22 at the top corners of the trench 16, the seed layer 20 of copper is deposited more thinly. Since the seed layer 20 is deposed by conventional PVD at a thickness of less than 500 Å, deposition of the seed layer 20 is not perfectly conformal, and thus the seed layer 20 may be discontinuous, failing to form on the partial sidewalls and the bottom corners 14 of the diffusion barrier layer 18 in the trench 16.

Referring to FIGS. 3b, during sequential copper ECP process, the copper filler 24 is plated only from the seed layer 20 and forming thereon. Therefore, voids 28 surrounded by the copper filler 24 and the diffusion barrier layer 18 may appear on the partial sidewalls and the bottom corners of the trench 16 without the seed layer 20 formed thereon, thereby increasing the resistance of interconnect.

Furthermore, voids 28 adjacent to the diffusion barrier layer 18 may result in poor adhesion of the copper interconnect to the diffusion barrier layer 18 on the sidewalls and the bottom wall of the trench 16 and peelings of the copper interconnect.

Thus, in order to meet the demands of present semiconductor fabrication, it is necessary to develop a novel material and method for fabricating integrated circuit interconnects with high aspect ratio trenches, reducing void formation and increasing adhesion of interconnect to the trench.

### SUMMARY

Accordingly, provided is an embodiment of a semiconductor device, comprising a substrate, an electroactive organic layer with conformal step coverage, and a metal layer. The substrate is a conductive substrate, or nonconductive substrate with a conductive layer formed thereon. An electroactive organic layer and metal layer are formed sequentially on the conductive substrate or the conductive layer, wherein the electroactive organic layer comprising metal atoms serves as a seed layer.

Embodiments of the invention provide an interconnection structure, comprising a substrate with an opening therein, an electroactive organic layer comprising metal atoms, and a metal layer. The electroactive organic layer is disposed on the sidewalls and the bottom wall of the opening, serving as seed layer. The metal layer is formed from the electroactive organic layer to fill the trench.

Embodiments of the invention also provide a damascene structure, comprising a substrate with a contact region, a dielectric layer, a conductive layer, and an organic/inorganic hybrid conductive layer. The dielectric layer, with a damascene pattern exposing the contact region, is formed on the substrate. The conductive layer is formed on the sidewalls and the bottom wall of the damascene pattern. The organic/inorganic hybrid conductive layer is formed from the-conductive layer, filling the damascene pattern.

Further provided is a method for fabricating a semiconductor device. A substrate is provided. An electroactive organic layer comprising metal atoms is formed on the substrate or the conductive layer. A metal layer is formed from the electroactive organic layer comprising metal atoms. Wherein, the substrate is a conductive substrate or a nonconductive substrate with a conductive layer formed thereon.

Embodiments of the invention provide a method for forming an interconnection structure. A substrate with an opening thereinto is provided. An electroactive organic layer is, conformally formed on the sidewalls and the bottom wall of the opening. A metal layer is formed from the electroactive organic layer, with the electroactive organic layer acting as a seed layer, to fill the opening.

Embodiments of the invention also provide a method for forming a damascene structure. A substrate with a contact region is provided. A dielectric layer is formed on the substrate and etched to form damascene pattern exposing the contact region. A conductive layer is conformally formed on the sidewalls and the bottom wall of the damascene pattern. An organic/inorganic hybrid conductive layer is formed from the conductive layer to fill the damascene pattern.

A detailed description is given in the following embodiments with reference to the accompanying drawings

### BRIEF DESCRIPTION OF THE DRAWINGS

Embodiments of the invention can be more fully understood by reading the subsequent detailed description in conjunction with the examples and references made to the accompanying drawings, wherein:

FIGS. 1a to 1c are cross-sections of a process for forming a conventional copper interconnection.

FIGS. 2a and 2b are cross-sections of a conventional copper trench interconnection formed from a seed layer, with overhangs.

FIGS. 3a and 3b are cross-sections of another conventional copper trench interconnection formed from a discontinuous seed layer.

FIGS. 4a to 4c are cross-sections of an embodiment of a method for forming a semiconductor device.

FIG. 5 is a schematic diagram of an embodiment of a trench interconnection.

FIG. 6 is a schematic diagram of an embodiment of a trench interconnection.

FIGS. 7a to 7c are cross sections of an embodiment of a method for forming trench interconnection.

FIG. 8 is a schematic diagram of an embodiment of a damascene structure.

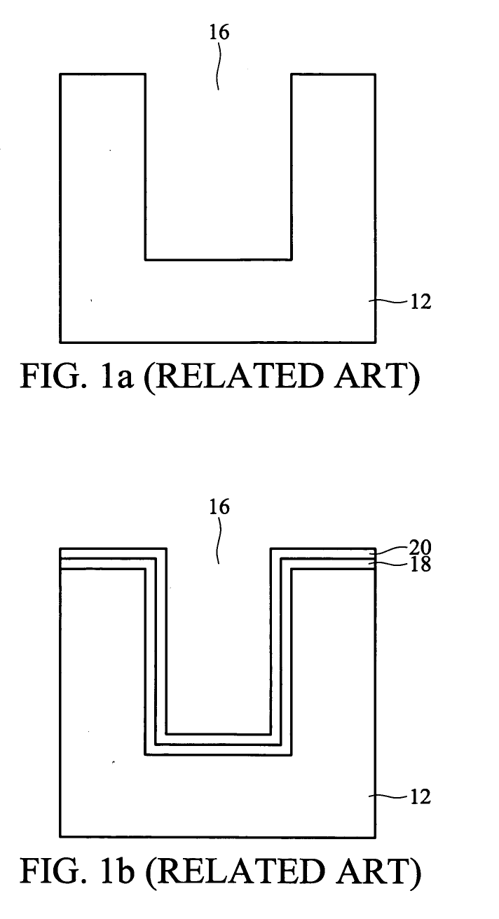

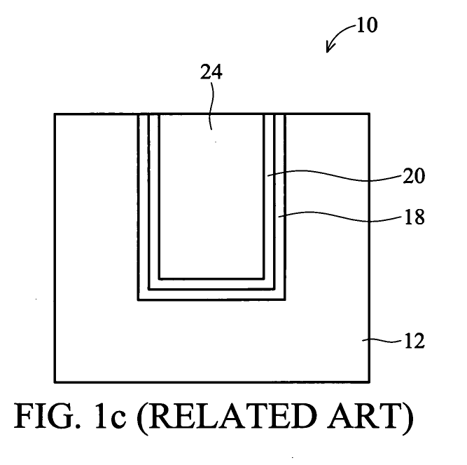

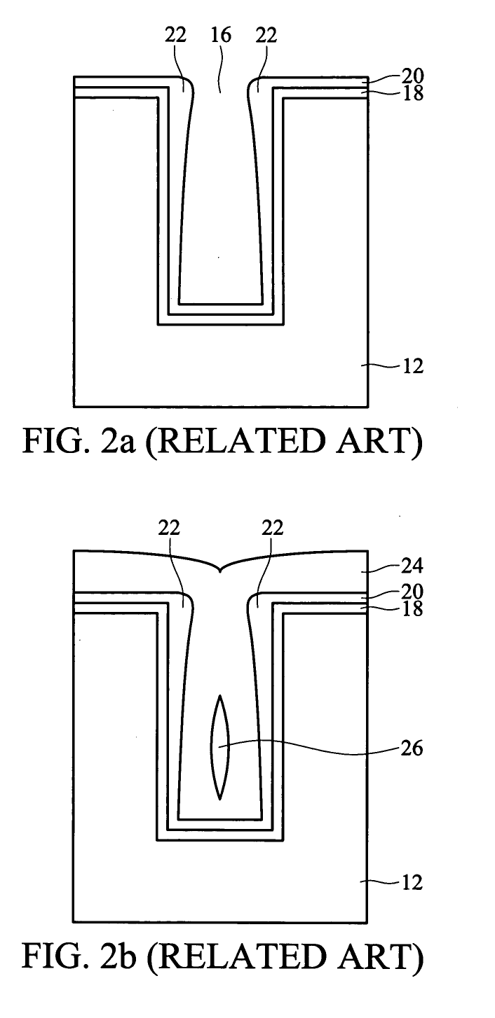

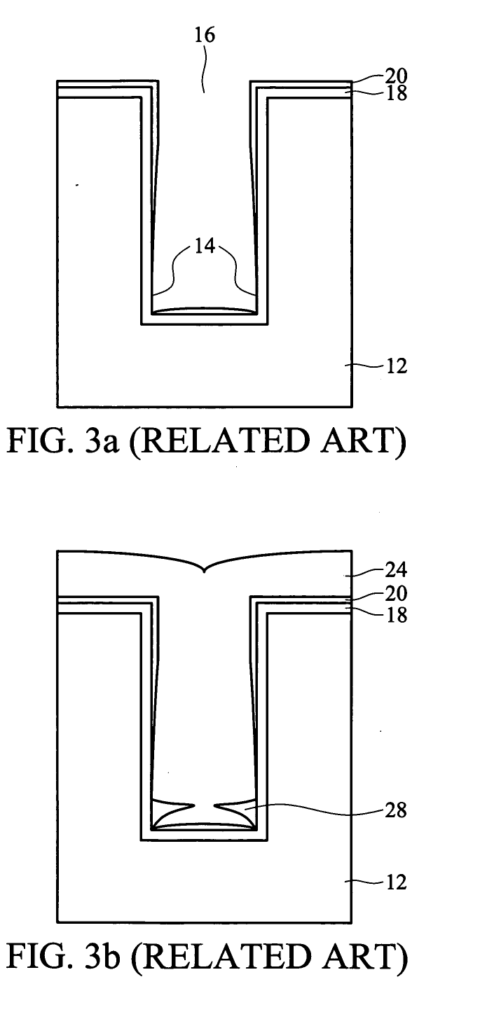

### DETAILED DESCRIPTION

The semiconductor device according to embodiments of the invention comprises an electroactive organic layer with conformal step coverage and uniform thickness. Since the electroactive organic layer comprises metal atoms, the electroactive organic layer can be used as seed layer facilitating the formation of metal layer formed thereon. In addition, embodiments of the invention provide a trench interconnection comprising an electroactive organic layer conformally and uniformly covering the sidewalls and the bottom wall of the trench, without overhangs and interruptions. The electroactive organic layer with conformal step coverage and uniform thickness further comprises metal atoms and serves as a seed layer resulting in the trench filled completely with the metal layer formed subsequently, avoiding the formation of voids and preventing resistance from developing.

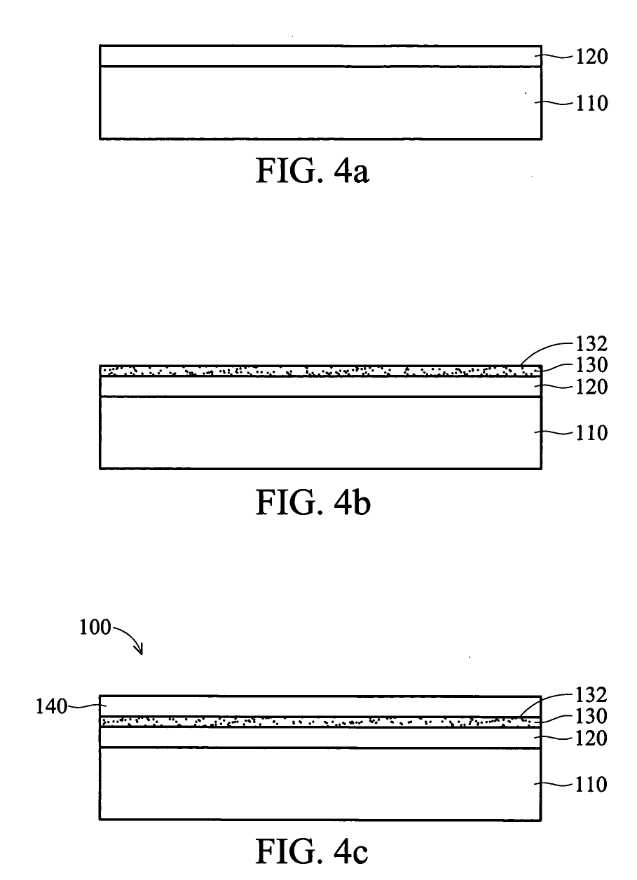

In FIG. 4a, a substrate 110 is provided, and can be a conductive substrate, such as Fe—Ni—Cr substrate, Fe—Cr substrate, Fe—Ni substrate, Fe—C substrate, or a nonconductive substrate with a conductive layer formed thereon. The nonconductive substrate can be a silicon substrate, silicon on insulator substrate (SOI), or substrate containing atoms of Group III˜V of the periodic table.

Suitable materials for the conductive layer include metal, metal nitride, alloy, or a combination thereof. Preferably, the conductive layer is a diffusion barrier layer, comprising tantalum, tantalum nitride, titanium, titanium nitride, tungsten, or a combination thereof. Herein, the substrate 110 is a silicon substrate with a diffusion barrier layer 120 formed thereon. Use of the term substrate includes devices formed within a semiconductor wafer and the layers overlying the wafer, and the accompanying drawings show the substrate 110 as a plain rectangle in order to simplify the illustration.

Referring to FIG. 4b, an electroactive organic layer 130 comprising metal atoms 132 is formed conformally and uniformly on the barrier layer, 120, thickness of 5 Å to 100 nm, preferably of 10 Å to 20 nm. The electroactive organic layer comprises reaction products of an electroactive organic compound and a metal ion. A method of forming the electroactive organic layer can comprise a voltage applied to the barrier layer 120, causing a current density of 0.1˜30 mA/cm², preferably 1˜15 mA/cm² in the barrier layer 120. An electroactive organic compound and metal ions are provided to react with the surface of the barrier layer 120 via electrochemical reaction to in-situ form the electroactive organic layer 130 comprising metal atoms 132 on the barrier layer 120.

The electroactive organic layer can alternatively be formed by a voltage applied to the barrier layer 120, causing a current density of 0.1˜30 mA/cm², preferably 1˜15 mA/cm², in the barrier layer 120. An electroactive organic compound is provided to react with the surface of the barrier layer 120, and an electrochemical reaction performed to form a pre-electroactive layer (not shown). Metal ions are processed on the pre-electroactive layer.

The electroactive organic compound can comprise electroactive conjugated polymers, such as polyaniline, polypyrrole, polythiophene, polyacetylene, poly(para-phenylene), poly(p-phenylene vinylene), poly-4-vinyl pyrridine, or a derivative thereof. The electroactive organic compound can be electroactive monomers, such as aniline, thiophene, pyrrole, bithiophene, acetylene, styrene, biphenyl, terphenyl, phenylene vinylene, 4-vinyl pyrridine or a derivative thereof. “Derivative” herein describes a polymer (or monomer) having substituent functional groups, such as, but not limited to, fluorine atom, halogen atom, alkyl group, alkoxy group, phenyl group, phenoxy group, heterocyclic group, cyano group, halogen atom, trifluoromethyl group, silyl group, and the like. The metal ions can be Cu ion, Pt ion, Ni ion, Al ion, Au ion, Ag ion, Sn ion, or a combination thereof, derived from a metal or metal complex through reduction or ionization. The metal ions can be Cu ions from Cu, copper sulfate, copper acetate, copper phosphate, copper nitrate, cuprous chloride, copper chloride, or copper bromide. The metal ions can be Pt ion and derived from Pt, platinum chloride, or platinum bromide. The weight ratio between the electroactive organic compound and the metal or metal complex is from 1:50 to 50:1.

The electroactive organic compound can be 4-vinyl pyrridine, with the method of forming electroactive organic layer comprising a voltage applied to the barrier layer 120, resulting in an effective negative charge on the surface thereof. Next, the negative charge of the barrier layer 120 electroactives 4-vinyl pyrridine, drawn thereto and reacting with the surface of the barrier layer 120 to be grafted thereonto. The grafted 4-vinyl pyrridine further reacts with reactivable 4-vinyl pyrridine via polymerization to form the electractive organic layer. Metal ions, such as Cu ions, are processed onto the electractive organic layer while the surface of the barrier layer 120 reacts with 4-vinyl pyrridine. Furthermore, Cu ions can be processed into the electractive organic layer when the polymerization performs a period of time. Resulting reactions are shown as follows.

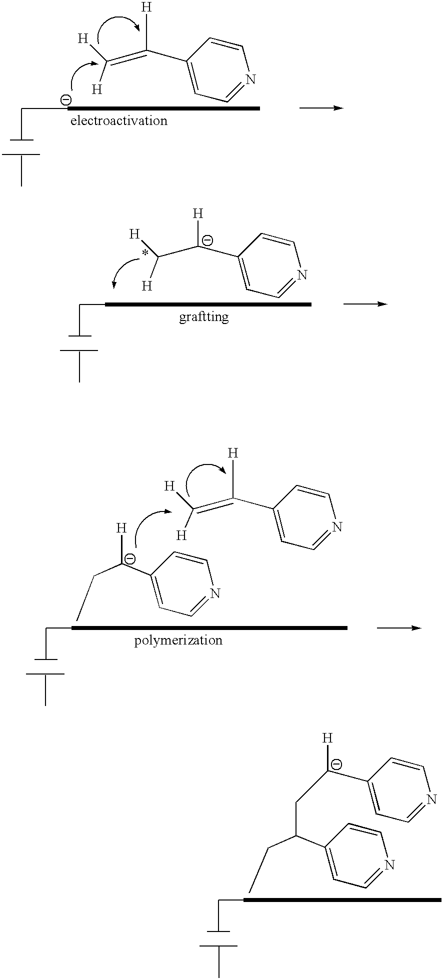

Referring to FIG. 4c, a metal layer 140 is conformally formed from the electroactive organic layer 130, with the electroactive organic layer 130 acting as a seed layer. Fabrication of the semiconductor device 100 is complete. Suitable materials for the metal layer include Cu, Ni, Pt, Al, Au, Ag, Sn or a combination thereof, formed by ectroless plating, chemical electroplating or wet plating. To reduce the resistivity of the metal layer 140, an annealing process at 150-400° C. can be performed.

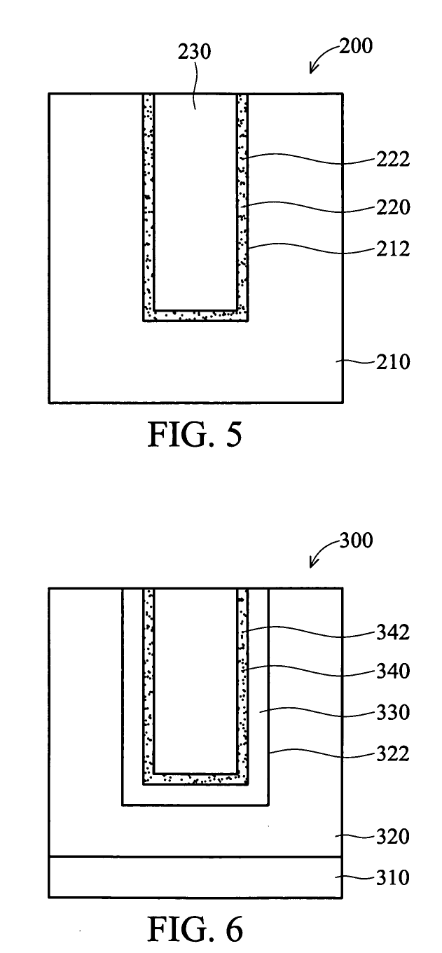

FIG. 5 illustrates a trench interconnection 200, and the method for fabricated as follows.

First, a conductive substrate 210 is provided and etched to create a trench 212 therein by lithography. A voltage applied to the conductive substrate 210 results in the surface reacting with an electroactive organic compound and metal ions via electrochemical reaction to conformally form an electroactive organic layer 220 comprising metal atoms 222 on the substrate 210, covering the sidewalls and the bottom wall of the trench 212. The electroactive organic layer 220 has a thickness of 5 Å to 100 nm, preferably of 10 Å to 20 nm.

Since the electroactive organic layer 220 is formed in-situ from the surface of the conductive substrate 210 via electrochemical reaction, the electroactive organic layer 220 can be formed on the substrate 210 with conformal step coverage and uniform thickness.

Next, a metal layer 230 is formed from the electroactive organic layer 220, filling the trench 212, with the electroactive organic layer 220 acting as a seed layer. Finally, the excess metal layer 230 overlying the trench 212 and the top surface of the substrate 210, as well as the electroactive organic layer on the field, are removed, for example, by mechanical polishing or chemical mechanical polishing (CMP), completing fabrication of trench interconnect 200. To reduce the resistivity of the metal layer 230, annealing at 150-400° C. can be performed.

FIG. 6 illustrates a trench interconnection 300, and the method for fabricating the same is described in detail as below.

A nonconductive substrate 310 with a dielectric layer 320 formed thereon is provided. Suitable materials of the dielectric layer 320 include oxide, nitride, or silicon-containing compound, such as silicon oxide, silicon nitride, or silicon oxy-nitride. Next, the dielectric layer 320 is etched to form a trench 322 therein by lithography. Next, a conductive layer 330 is conformally formed on the dielectric layer 320, covering the sidewalls and the bottom wall of the trench 322. Suitable materials for the conductive layer 330 are metal, metal nitride, alloy, or a combination thereof. Preferably, the conductive layer 330 is a diffusion barrier layer, comprising tantalum, tantalum nitride, titanium, titanium nitride, tungsten, or a combination thereof.

A voltage applied to the conductive layer 330 results in the surface reacting with an electroactive organic compound and metal ions electrochemically to conformally form an electroactive organic layer 340 comprising metal atoms 342 on the conductive layer 330, covering the sidewalls and the bottom wall of the trench 322. The electroactive organic layer 340 has a thickness of 5 Å to 100 nm, preferably of 10 Å to 20 nm.

Next, a metal layer 350 is formed from the electroactive organic layer 340, filling the trench 322, with the electroactive organic layer 340 acting as a seed layer. Finally, the excess metal layer 350 overlying the trench 322 and the top surface of the dielectric layer 320, as well as the conductive layer 330 and electroactive organic layer 340 on the field, are removed, for example, by mechanical polishing or chemical mechanical polishing (CMP), completing fabrication of trench interconnect 300. To reduce the resistivity of the metal layer 350, annealing at 150-400° C. can be performed.

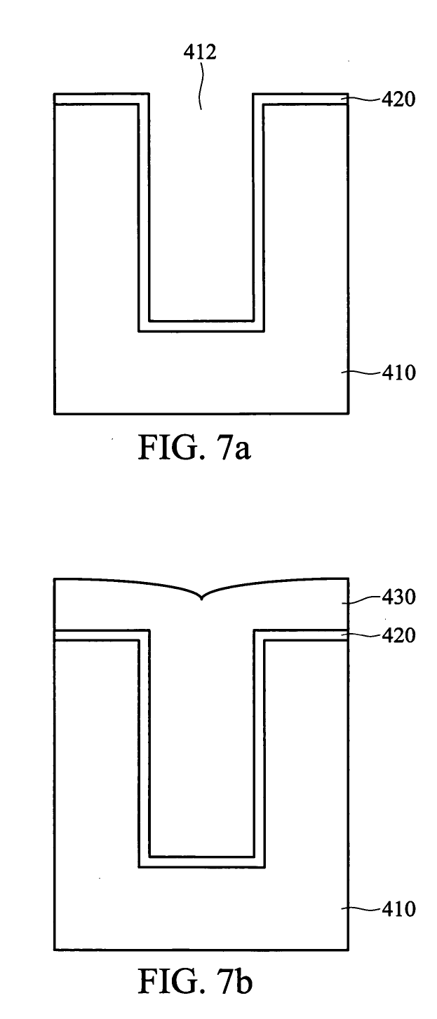

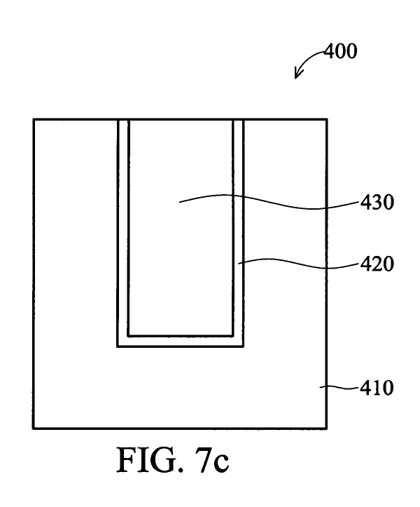

FIGS. 7a-7c, show an embodiment of a trench interconnection, comprising a substrate 410 with a trench 412 is provided. The substrate 410 can be a conductive substrate, such as Fe—Ni—Cr substrate, Fe—Cr substrate, Fe—Ni substrate, or Fe—C substrate, or a nonconductive substrate with a conductive layer formed thereon, such as a silicon substrate, silicon on insulator substrate (SOI), or substrate containing atom of Group III˜V of the periodic table.

Suitable materials for the conductive layer include metal, metal nitride, alloy, or a combination thereof. Preferably, the conductive layer is a diffusion barrier layer, comprising tantalum, tantalum nitride, titanium, titanium nitride, tungsten, or a combination thereof. Herein, the substrate 410 is a silicon substrate with a diffusion barrier layer 420 formed thereon. Use of the term substrate includes devices formed within a semiconductor wafer and the layers overlying the wafer, and the accompanying drawings show the substrate 410 in a plain rectangle in order to simplify the illustration.

Referring to FIG. 7b, an organic/inorganic hybrid conductive layer 430 is formed conformally and uniformly on the barrier layer 420, filling the trench completely. A voltage applied to the barrier layer 420 causes a current density of 0.1˜30 mA/cm², preferably 1˜15 mA/cm² in the barrier layer 420. A solution comprising an electroactive organic compound and a metal or metal complex is provided to react with the surface of the barrier layer 420 electrochemically to form the organic/inorganic hybrid conductive layer 430.

The electroactive organic compound can be electroactive conjugated polymers, such as polyaniline, polypyrrole, polythiophene, polyacetylene, poly(para-phenylene), poly(p-phenylene vinylene), poly-4-vinyl pyrridine, or a derivative thereof. The electroactive organic compound can comprise electroactive monomers, such as aniline, thiophene, pyrrole, bithiophene, acetylene, styrene, biphenyl, terphenyl, phenylene vinylene, 4-vinyl pyrridine or a derivative thereof. “Derivative” herein means a polymer (or monomer) having substituent functional groups, such as, but not limited to, fluorine atom, halogen atom, alkyl group, alkoxy group, phenyl group, phenoxy group, heterocyclic group, cyano group, halogen atom, trifluoromethyl group, silyl group, and the like. The metal or metal complex comprises Cu, Pt, Ni, Al, Au, Ag, Sn, or a combination thereof. The metal complex can also be copper sulfate, copper acetate, copper phosphate, copper nitrate, cuprous chloride, copper chloride, copper bromide, platinum chloride, or platinum bromide. It is noted that the weight ratio between the electroactive organic compound and the metal or metal complex is from 1:50 to 50:1.

Finally, referring to FIG. 7c, the excess organic/inorganic hybrid conductive layer 430 overlying the trench 412 and the top surface of the substrate 410, as well as the barrier layer 420 and the organic/inorganic hybrid conductive layer 430 on the field, are removed by, for example, mechanical polishing or chemical mechanical polishing (CMP). The fabrication of the trench interconnect 400 is complete.

The semiconductor device according to some embodiments of the invention comprises an organic/inorganic hybrid conductive layer with conformal step coverage and uniform thickness filling the trench without gaps or voids, which may prevent resistance.

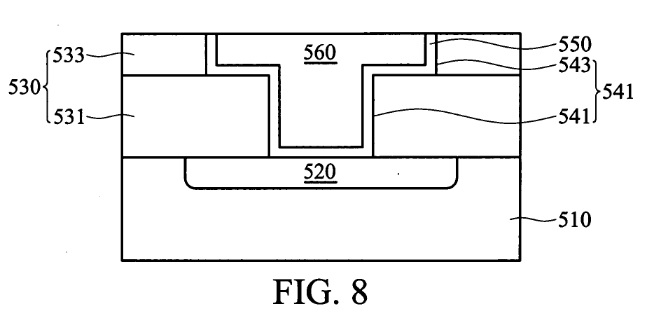

FIG. 8 illustrates a damascene structure 500, and the method for fabricating the same is described in detail as below.

A substrate 510, such as a silicon substrate, silicon on insulator substrate (SOI), or substrate containing atom of Group III˜V of the periodic table, with a contact region 520 is provided. The contact region 520 can be an active element or a conductive line. A dielectric layer 530 is formed over the substrate 510 and the contact region 520. Next, the dielectric layer 530 is patterned to form a damascene pattern 540 thereinto, exposing the surface of the contact region 520. Particularly, the dielectric layer can comprise a first dielectric layer 531 and a second dielectric layer 533, and the damascene pattern 540 comprise a via hole 541 and interconnect trench 543. The first and second dielectric layer can comprise plasma oxide, HDP oxide, dielectric with high resistance to mechanical stress, low-k dielectrics, fluorinated silicate glass (FSG), porous silicate glass or silicon-based dielectrics.

Next, a conductive layer 550, such as a diffusion barrier layer, is conformally formed on the dielectric layer 530 to cover the sidewalls and the bottom wall of the damascene pattern 540. Next, an organic/inorganic hybrid conductive layer 560 is formed from the conductive layer 550 to fill the damascene pattern 540 completely and electrically connect to the contact region. The steps for forming the organic/inorganic hybrid conductive layer 560 are as follows. A voltage applied to the conductive layer 550 causes a current density of 0.1˜30 mA/cm², preferably 1˜15 mA/cm² in the conductive layer 550. A solution comprising an electroactive organic compound and a metal or metal complex is provided to react with the surface of the conductive layer 550 electrochemically to form the organic/inorganic hybrid conductive layer 560. Suitable materials for the conductive layer, the electroactive organic compound, and the metal or metal complex are the same as those used in the embodiment of FIGS. 7a-7c. It is noted that the weight ratio between the electroactive organic compound and the metal or metal complex is from 1:50 to 50:1.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. A semiconductor device, comprising:
a substrate;
a metal layer;
an electroactive organic layer comprising metal atoms, serving as seed layer, sandwiched in between and in intimate contact with both the metal layer and the substrate.

2. The semiconductor device as claimed in claim 1, wherein the substrate is a conductive substrate, or a nonconductive substrate with a conductive layer thereon.

3. The semiconductor device as claimed in claim 1, wherein the substrate comprises silicon, silicon on insulator (SOI), or contains atoms of Group III˜V of the periodic table.

4. The semiconductor device as claimed in claim 2, wherein the conductive layer comprises metal, metal nitride, alloy, or a combination thereof.

5. The semiconductor device as claimed in claim 2, wherein the conductive layer is a diffusion barrier layer, comprising tantalum, tantalum nitride, titanium, titanium nitride, tungsten, or a combination thereof.

6. The semiconductor device as claimed in claim 1, wherein the electroactive organic layer comprises reaction products of an electroactive organic compound and a metal ion.

7. The semiconductor device as claimed in claim 6, wherein the electroactive organic compound is an electroactive conjugated polymer comprising polyaniline, polypyrrole, polythiophene, polyacetylene, poly(para-phenylene), poly(p-phenylene vinylene), poly-4-vinyl pyrridine, or a derivative thereof.

8. The semiconductor device as claimed in claim 6, wherein the electroactive organic compound is an electroactive monomer, comprising aniline, thiophene, pyrrole, bithiophene, acetylene, styrene, biphenyl, terphenyl, phenylene vinylene, 4-vinyl pyrridine, or a derivative thereof.

9. The semiconductor device as claimed in claim 6, wherein the metal ion comprises Cu, Pt, Ni, Al, Au, Ag, or Sn.

10. The semiconductor device as claimed in claim 1, wherein the electroactive organic layer comprises reaction products of an electroactive organic compound and a metal ion derived from a metal or metal complex.

11. The semiconductor device as claimed in claim 10, wherein the weight ratio between the electroactive organic compound and the metal or metal complex is from 1:50 to 50:1.

12. The semiconductor device as claimed in claim 1, wherein the electroactive organic layer has a thickness of 5 Å to 100 nm.

13. The semiconductor device as claimed in claim 1, wherein the metal layer comprises Cu, Ni, Pt, Al, Au, Ag, Sn, or a combination thereof.

14. An interconnection structure, comprising:
a substrate with an opening therein;
an electroactive organic layer comprising metal atoms on the sidewalls and the bottom wall of the opening, serving as seed layer; and
a metal layer on the electroactive organic layer to fill the opening.

15. The interconnection structure as claimed in claim 14, wherein the substrate is a conductive substrate, or a nonconductive substrate with a conductive layer thereon.

16. The interconnection structure as claimed in claim 14, wherein the substrate comprises silicon, silicon on insulator (SOI), or contains atoms of Group III˜V of the periodic table.

17. The interconnection structure as claimed in claim 15, wherein the conductive layer comprises metal, metal nitride, alloy, or a combination thereof.

18. The interconnection structure as claimed in claim 15, wherein the conductive layer is a diffusion barrier layer, comprising tantalum, tantalum nitride, titanium, titanium nitride, tungsten, or a combination thereof.

19. The interconnection structure as claimed in claim 14, wherein the electroactive organic layer comprises reaction products of an electroactive organic compound and a metal ion derived from a metal or metal complex.

20. The interconnection structure as claimed in claim 19, wherein the electroactive organic compound is an electroactive conjugated polymer comprising polyaniline, polypyrrole, polythiophene, polyacetylene, poly(para-phenylene), poly(p-phenylene vinylene), poly-4-vinyl pyrridine, or a derivative thereof.

21. The interconnection structure as claimed in claim 19, wherein the electroactive organic compound is an electroactive monomer, comprising aniline, thiophene, pyrrole, bithiophene, acetylene, styrene, biphenyl, terphenyl, phenylene vinylene, 4-vinyl pyrridine, or a derivative thereof.

22. The interconnection structure as claimed in claim 19, wherein the metal ion comprises Cu, Pt, Ni, Al, Au, Ag, or Sn.

23. The interconnection structure as claimed in claim 14, wherein the metal layer comprises Cu, Ni, Pt, Al, Au, Ag, Sn, or a combination thereof.

24. A damascene structure, comprising:
a substrate;
a dielectric layer, with a damascene pattern to expose a contact region, on the substrate;
a conductive layer on the sidewalls and the bottom wall of the damascene pattern; and
an organic/inorganic hybrid conductive layer formed from the conductive layer to fill the damascene pattern.

25. The damascene structure as claimed in claim 24, wherein the substrate comprises silicon, silicon on insulator (SOI), or contains atoms of Groups III˜V of the periodic table.

26. The damascene structure as claimed in claim 24, wherein the conductive layer comprises metal, metal nitride, alloy, or a combination thereof.

27. The damascene structure as claimed in claim 24, wherein the conductive layer is a diffusion barrier layer, comprising tantalum, tantalum nitride, titanium, titanium nitride, tungsten, or a combination thereof.

28. The damascene structure as claimed in claim 24, wherein the organic/inorganic hybrid conductive layer comprises reaction products of an electroactive organic compound and a metal or metal complex.

29. The damascene structure as claimed in claim 28, wherein the electroactive organic compound is an electroactive conjugated polymer, comprising polyaniline, polypyrrole, polythiophene, polyacetylene, poly(para-phenylene), poly(p-phenylene vinylene), poly-4-vinyl pyrridine, or a derivative thereof.

30. The damascene structure as claimed in claim 28, wherein the electroactive organic compound is an electroactive monomer, comprising aniline, thiophene, pyrrole, bithiophene, acetylene, styrene, biphenyl, terphenyl, phenylene vinylene, 4-vinyl pyrridine, or a derivative thereof.

31. The damascene structure as claimed in claim 28, wherein the metal or metal complex comprises Cu, Pt, Ni, Al, Au, Ag, or Sn.

32. A method for forming a semiconductor device, comprising:
providing a substrate;
conformally forming an electroactive organic layer comprising metal atoms on the substrate; and
conformally forming a metal layer from the electroactive organic layer with the electroactive organic layer acting as a seed layer.

33. The method as claimed in claim 32, wherein the substrate is a conductive substrate, or a nonconductive substrate with a conductive layer thereon.

34. The method as claimed in claim 33, wherein the conductive layer comprises metal, metal nitride, alloy, or a combination thereof.

35. The method as claimed in claim 33, wherein the nonconductive substrate comprises silicon, silicon on insulator (SOI), or contains atoms of Groups III˜V of the periodic table.

36. The method as claimed in claim 33, wherein the conductive layer comprises metal, metal nitride, alloy, or a combination thereof.

37. The method as claimed in claim 33, wherein the conductive layer is a diffusion barrier layer, comprising tantalum, tantalum nitride, titanium, titanium nitride, tungsten, or a combination thereof.

38. The method as claimed in claim 32, wherein formation of the electroactive organic layer comprise reacting an electroactive organic compound and a metal ion from the surface of the substrate.

39. The method as claimed in claim 38, wherein the electroactive organic compound is an electroactive conjugated polymer, comprising polyaniline, polypyrrole, polythiophene, polyacetylene, poly(para-phenylene), poly(p-phenylene vinylene), poly-4-vinyl pyrridine, or a derivative thereof.

40. The method as claimed in claim 38, wherein the electroactive organic compound is an electroactive monomer, comprising aniline, thiophene, pyrrole, bithiophene, acetylene, styrene, biphenyl, terphenyl, phenylene vinylene, 4-vinyl pyrridine, or a derivative thereof.

41. The method as claimed in claim 38, wherein the metal ion comprises Cu, Pt, Ni, Al, Au, Ag, or Sn.

42. The method as claimed in claim 38, wherein the metal ion is derived from a metal or metal compound through reduction or ionization.

43. The method as claimed in claim 32, wherein formation of the electroactive organic layer comprises:
reacting an electroactive organic compound with the surface of the substrate electrochemically by applying voltage to the substrate to form a pre-electroactive organic layer; and
processing a metal ion into the pre-electroactive organic layer when the electrochemical reaction performs a period of time.

44. The method as claimed in claim 43, wherein the electroactive organic compound is an electroactive conjugated polymer, comprising polyaniline, polypyrrole, polythiophene, polyacetylene, poly(para-phenylene), poly(p-phenylene vinylene), poly-4-vinyl pyrridine, or a derivative thereof.

45. The method as claimed in claim 43, wherein the electroactive organic compound is an electroactive monomer, comprising aniline, thiophene, pyrrole, bithiophene, acetylene, styrene, biphenyl, terphenyl, phenylene vinylene, 4-vinyl pyrridine, or a derivative thereof.

46. The method as claimed in claim 43, wherein the metal ion comprises Cu, Pt, Ni, Al, Au, Ag, or Sn.

47. The method as claimed in claim 43, wherein the metal ion is derived from a metal or metal compound through reduction or ionization.

48. The method as claimed in claim 43, wherein the metal layer comprises Cu, Ni, Pt, Al, Au, Ag, Sn, or a combination thereof.

49. The method as claimed in claim 32, wherein conformal formation of the metal layer from the electroactive organic layer uses electroless plating, chemical electroplating, or wet plating.

50. A method for forming an interconnection structure, comprising:
providing a substrate with an opening thereinto;
conformally forming an electroactive organic layer on the sidewalls and the bottom wall of the opening; and
forming a metal layer from the electroactive organic layer, with the electroactive organic layer acting as a seed layer, to fill the opening.

51. The method as claimed in claim 50, wherein the substrate is a conductive substrate, or a nonconductive substrate with a conductive layer thereon.

52. The method as claimed in claim 51, wherein the conductive layer comprises metal, metal nitride, alloy, or a combination thereof.

53. The method as claimed in claim 51, wherein the nonconductive substrate comprises silicon, silicon on insulator (SOI), or contains atoms of Groups III˜V of the, periodic table.

54. The method as claimed in claim 51, wherein the conductive layer comprises metal, metal nitride, alloy, or a combination thereof.

55. The method as claimed in claim 51, wherein the conductive layer is a diffusion barrier layer, comprising tantalum, tantalum nitride, titanium, titanium nitride, tungsten, or a combination thereof.

56. The method as claimed in claim 51, wherein formation of the electroactive organic layer comprise reacting an electroactive organic compound and a metal ion from the surface of the substrate.

57. The method as claimed in claim 56, wherein the electroactive organic compound is an electroactive conjugated polymer, comprising polyaniline, polypyrrole, polythiophene, polyacetylene, poly(para-phenylene), poly(p-phenylene vinylene), poly-4-Vinyl pyrridine, or a derivative thereof.

58. The method as claimed in claim 56, wherein the electroactive organic compound is an electroactive monomer, comprising aniline, thiophene, pyrrole, bithiophene, acetylene, styrene, biphenyl, terphenyl, phenylene vinylene, 4-vinyl pyrridine, or a derivative thereof.

59. The method as claimed in claim 56, wherein the metal ion comprises Cu, Pt, Ni, Al, Au, Ag, or Sn.

60. The method as claimed in claim 56, wherein the metal ion is derived from a metal or metal compound through reduction or ionization.

61. The method as claimed in claim 50, wherein conformal formation of the metal layer from the electroactive organic layer uses electroless plating, chemical electroplating, or wet plating.

62. A method for forming a damascene structure, comprising:
providing a substrate with a contact region;
forming a dielectric layer with a damascene pattern on the substrate to expose the contact region;
conformally forming a conductive layer on the sidewalls and the bottom wall of the damascene pattern; and
forming an organic/inorganic hybrid conductive layer from the conductive layer to fill the damascene pattern.

63. The method as claimed in claim 62, wherein the substrate comprises silicon, silicon on insulator (SOI), or contains atoms of Groups III˜V of the periodic table.

64. The method as claimed in claim 62, wherein the conductive layer comprises metal, metal nitride, alloy, or a combination thereof.

65. The method as claimed in claim 62, wherein the conductive layer is a diffusion barrier layer, comprising tantalum, tantalum nitride, titanium, titanium nitride, tungsten, or a combination thereof.

66. The method as claimed in claim 62, wherein formation of the organic/inorganic hybrid conductive layer comprises reacting a solution, comprising an electroactive organic compound and a metal or metal complex, with the surface of the conductive layer electrochemically by applying voltage to the conductive layer.

67. The method as claimed in claim 66, wherein the electroactive organic compound is an electroactive conjugated polymer, comprising polyaniline, polypyrrole, polythiophene, polyacetylene, poly(para-phenylene), poly(p-phenylene vinylene), poly-4-vinyl pyrridine, or a derivative thereof.

68. The method as claimed in claim 66, wherein the electroactive organic compound is an electroactive monomer, comprising aniline, thiophene, pyrrole, bithiophene, acetylene, styrene, biphenyl, terphenyl, phenylene vinylene, 4-vinyl pyrridine, or a derivative thereof.

69. The method as claimed in claim 66, wherein the metal or metal complex comprises Cu, Pt, Ni, Al, Au, Ag, or Sn.
